(19) United States
(12) Patent Application Publication
(10) Pub. No.: US 2026/0150230 A1
(43) Pub. Date: May 28, 2026

(54) IMMERSION COOLING TANK

(71) Applicant: Auradine, Inc., Santa Clara, CA (US)

(72) Inventors: Nicholas Cabi, San Jose, CA (US); Gagan Agarwal, Palo Alto, CA (US); Darshan Shah, Milpitas, CA (US); Glen Gibson, Santa Clara, CA (US)

(21) Appl. No.: 18/960,771

(22) Filed: Nov. 26, 2024

(51) Int. Cl. H05K 7/20

(52) U.S. Cl. CPC H05K 7/20236; H05K 7/20263; H05K 7/20272; H05K 7/20281

(57) ABSTRACT

Some aspects of the present disclosure involve monitoring an immersion cooling tank to detect and/or mitigate unsafe operating conditions. In one aspect, a method includes: receiving measurement data from one or more sensors that are configured to measure operating conditions of an immersion tank that includes a dielectric cooling fluid and/or one or more electronic devices that are configured to perform computing operations while submerged in the dielectric cooling fluid of the immersion tank; determining that at least one operating condition of the immersion tank or the one or more electronic devices is outside of a threshold range based on the measurement data received from the one or more sensors; and performing at least one remedial action in response to determining that the at least one operating condition of the immersion tank or the one or more electronic devices is outside of the threshold range.

### TECHNICAL FIELD

The present disclosure generally relates to an immersion cooling tank that monitors characteristics of an immersion cooling fluid disposed therein.

### BACKGROUND

Immersion cooling fluid is a specialized dielectric substance used in immersion cooling tanks to submerge electronic components, such as high-performance computing devices, servers and data center equipment, for efficient heat dissipation. In some cases, however, the immersion cooling fluid may become contaminated by various substances, which can compromise the thermal conductivity of the fluid and potentially lead to equipment overheating, corrosion, or even complete system failure.

### SUMMARY

One aspect of the present disclosure relates to an apparatus including: an immersion tank configured to hold a volume of dielectric cooling fluid; one or more sensors configured to measure operating conditions of at least one of the immersion tank or one or more electronic devices that are configured to perform computing operations while submerged in the dielectric cooling fluid of the immersion tank; and a control system including one or more processors configured to: receive measurement data from the one or more sensors; determine that at least one operating condition of the immersion tank or the one or more electronic devices is outside of a threshold range based on the measurement data received from the one or more sensors; and perform at least one remedial action in response to determining that the at least one operating condition of the immersion tank or the one or more electronic devices is outside of the threshold range.

In some implementations, performing the remedial action includes transmitting a signal that causes the electronic devices in the immersion tank to shut down or enter a low power state until the at least one operating condition of the immersion tank or the one or more electronic devices is restored to the threshold range.

In some implementations, performing the remedial action includes: transmitting, to a mobile device associated with a system operator, a notification that the at least one operating condition of the immersion tank or the one or more electronic devices is outside of the threshold range; receiving, from the mobile device, an instruction to turn off the one or more electronic devices in the immersion tank; and transmitting a signal that causes the one or more electronic devices in the immersion tank to shut down or enter a low power state.

In some implementations, performing the remedial action includes transmitting, to a fleet management controller that orchestrates computing operations across a set of electronic devices including the one or more electronic devices, a notification that the at least one operating condition of the immersion tank or the one or more electronic devices is outside of the threshold range.

In some implementations, performing the remedial action includes initiating a cleaning process to filter contaminants from the dielectric cooling fluid based on determining that a contamination level of the dielectric cooling fluid is above a threshold value.

In some implementations, the one or more sensors include a conductivity sensor configured to measure a thermal or electrical conductivity of the dielectric cooling fluid in the immersion tank, and where determining that at least one operating condition of the immersion tank or the one or more electronic devices is outside of the threshold range includes determining that the thermal or electrical conductivity of the dielectric cooling fluid is outside of the threshold range based on measurements provided by the conductivity sensor.

In some implementations, the one or more sensors include a meter configured to measure a capacitance or resistance of the dielectric cooling fluid in the immersion tank, and where determining that at least one operating condition of the immersion tank or the one or more electronic devices is outside of the threshold range includes determining that the capacitance or resistance of the dielectric cooling fluid is outside of the threshold range based on measurements provided by the meter.

In some implementations, the one or more sensors include a fluid level sensor that is configured to measure the fluid level of the dielectric cooling fluid, and where determining that at least one operating condition of the immersion tank or the one or more electronic devices is outside of the threshold range includes detecting a leak in the immersion tank based on a change in the fluid level of the dielectric cooling fluid as measured by the fluid level sensor.

In some implementations, the one or more sensors include a temperature sensor configured to measure an operating temperature of the dielectric cooling fluid, and where determining that at least one operating condition of the immersion tank or the one or more electronic devices is outside of the threshold range includes determining that the operating temperature of the dielectric cooling is above a threshold based on measurements provided by the temperature sensor.

In some implementations, the one or more sensors include a pressure sensor configured to measure an operating pressure of the immersion tank, and where determining that at least one operating condition of the immersion tank or the one or more electronic devices is outside of the threshold range includes determining that the operating pressure of the immersion tank is above a threshold based on measurements provided by the pressure sensor.

In some implementations, the one or more sensors include an opacity sensor configured to measure an opacity of the dielectric cooling fluid, and where determining that at least one operating condition of the immersion tank or the one or more electronic devices is outside of the threshold range includes determining that a contamination level of the dielectric cooling fluid is above a threshold based on the opacity of the dielectric cooling fluid as measured by the opacity sensor.

In some implementations, determining that the at least one operating condition of the immersion tank or the one or more electronic devices is outside of the threshold range includes: accessing historical measurement data collected by the one or more sensors; analyzing the received measurement data based on the historical measurement data; and predicting that an operating condition of the immersion tank or the one or more electronic devices will leave the threshold range based on the analyzing.

In some implementations, the control system is configured to communicate with the one or more electronic devices in the immersion tank via a short-range wireless communication protocol.

In some implementations, the dielectric cooling fluid includes a single-phase immersion cooling liquid or a two-phase immersion cooling liquid.

In some implementations, the apparatus further includes: a heat exchanger configured to dissipate heat generated by the one or more electronic devices by means of the dielectric cooling fluid, where performing the remedial action includes adjusting an operating parameter of the heat exchanger to restore an operating temperature or pressure of the immersion tank to the threshold range.

In some implementations, the apparatus further includes: a pump system configured to circulate the dielectric cooling fluid through the immersion tank, where performing the remedial action includes adjusting an operating parameter of the pump system to restore an operating temperature or pressure of the immersion tank to the threshold range.

Another aspect of the present disclosure relates to a method including: receiving measurement data from one or more sensors that are configured to measure operating conditions of at least one of (i) an immersion tank including a dielectric cooling fluid or (ii) one or more electronic devices that are configured to perform computing operations while submerged in the dielectric cooling fluid of the immersion tank; determining that at least one operating condition of the immersion tank or the one or more electronic devices is outside of a threshold range based on the measurement data received from the one or more sensors; and performing at least one remedial action in response to determining that the at least one operating condition of the immersion tank or the one or more electronic devices is outside of the threshold range.

In some implementations, performing the remedial action includes transmitting a signal that causes the electronic devices in the immersion tank to shut down or enter a low power state until the at least one operating condition of the immersion tank or the one or more electronic devices is restored to the threshold range.

In some implementations, performing the remedial action includes: transmitting, to a mobile device associated with a system operator, a notification that the at least one operating condition of the immersion tank or the one or more electronic devices is outside of the threshold range; receiving, from the mobile device, an instruction to turn off the one or more electronic devices in the immersion tank; and transmitting a signal that causes the one or more electronic devices in the immersion tank to shut down or enter a low power state.

In some implementations, performing the remedial action includes initiating a cleaning process to filter contaminants from the dielectric cooling fluid based on determining that a contamination level of the dielectric cooling fluid is above a threshold value.

In some implementations, the one or more sensors include a conductivity sensor configured to measure a thermal or electrical conductivity of the dielectric cooling fluid in the immersion tank, and where determining that at least one operating condition of the immersion tank or the one or more electronic devices is outside of the threshold range includes determining that the thermal or electrical conductivity of the dielectric cooling fluid is outside of the threshold range based on measurements provided by the conductivity sensor.

In some implementations, the one or more sensors include a meter configured to measure a capacitance or resistance of the dielectric cooling fluid in the immersion tank, and where determining that at least one operating condition of the immersion tank or the one or more electronic devices is outside of the threshold range includes determining that the capacitance or resistance of the dielectric cooling fluid is outside of the threshold range based on measurements provided by the meter.

In some implementations, the one or more sensors include a fluid level sensor that is configured to measure the fluid level of the dielectric cooling fluid, and where determining that at least one operating condition of the immersion tank or the one or more electronic devices is outside of the threshold range includes detecting a leak in the immersion tank based on a change in the fluid level of the dielectric cooling fluid as measured by the fluid level sensor.

In some implementations, the one or more sensors include a temperature sensor configured to measure an operating temperature of the dielectric cooling fluid, and where determining that at least one operating condition of the immersion tank or the one or more electronic devices is outside of the threshold range includes determining that the operating temperature of the dielectric cooling fluid is above a threshold based on measurements provided by the temperature sensor.

In some implementations, the one or more sensors include a pressure sensor configured to measure an operating pressure of the immersion tank, and where determining that at least one operating condition of the immersion tank or the one or more electronic devices is outside of the threshold range includes determining that the operating pressure of the immersion tank is above a threshold based on measurements provided by the pressure sensor.

In some implementations, the one or more sensors include an opacity sensor configured to measure an opacity of the dielectric cooling fluid, and where determining that at least one operating condition of the immersion tank or the one or more electronic devices is outside of the threshold range includes determining that a contamination level of the dielectric cooling fluid is above a threshold based on the opacity of the dielectric cooling fluid as measured by the opacity sensor.

In some implementations, determining that the at least one operating condition of the immersion tank or the one or more electronic devices is outside of the threshold range includes: accessing historical measurement data collected by the one or more sensors; analyzing the received measurement data based on the historical measurement data; and predicting that an operating condition of the immersion tank or the one or more electronic devices will leave the threshold range based on the analyzing.

In some implementations, the immersion tank includes a control system that is configured to communicate with the one or more electronic devices in the immersion tank via a short-range wireless communication protocol.

In some implementations, the dielectric cooling fluid includes a single-phase immersion cooling liquid or a two-phase immersion cooling liquid.

In some implementations, the immersion tank includes a heat exchanger that is configured to dissipate heat generated by the one or more electronic devices by means of the dielectric cooling fluid, and where performing the remedial action includes adjusting an operating parameter of the heat exchanger to restore an operating temperature or pressure of the immersion tank to the threshold range.

In some implementations, the immersion tank includes a pump system that is configured to circulate the dielectric cooling fluid through the immersion tank, and where performing the remedial action includes adjusting an operating parameter of the pump system to restore an operating temperature or pressure of the immersion tank to the threshold range.

Another aspect of the present disclosure relates to an apparatus that includes one or more processors and memory storing instructions that, when executed, cause the apparatus to perform any of the foregoing operations.

Another aspect of the present disclosure relates to a non-transitory computer-readable medium storing instructions that, when executed, cause one or more processors to perform any of the foregoing operations.

### BRIEF DESCRIPTION OF THE FIGURES

FIG. 1A is a schematic diagram of an example single-phase immersion cooling system, according to some implementations.

FIG. 1B is a schematic diagram of an example dual-phase immersion cooling system, according to some implementations.

FIG. 2 is a schematic diagram of an example intelligent immersion cooling system, according to some implementations.

FIG. 3 is an example process flow for managing unsafe operating conditions of an intelligent immersion cooling tank, according to some implementations.

FIG. 4 is a flowchart of an example method for managing operating conditions of an intelligent immersion cooling tank, according to some implementations.

FIG. 5 is a schematic diagram of an example computer system, according to some implementations.

### DETAILED DESCRIPTION

An immersion cooling tank is a type of cooling apparatus that holds a thermally conductive but electrically non-conductive cooling fluid in which high-performance electronic devices, such as integrated circuit (IC) chips for hash computations, servers or computer processors, are submerged directly. Immersion cooling is used to efficiently remove heat from high-performance electronic devices, which allows for higher energy efficiency, reduced noise, and improved performance due to lower operating temperatures, e.g., perform high-rate operations without thermal breakdown. In some cases, the cooling fluid is a specialized dielectric substance (e.g., a single-phase or two-phase dielectric liquid) used in the immersion cooling tank to submerge electronic devices for efficient heat dissipation. By fully immersing these devices in the cooling fluid, heat is directly transferred from the electronics to the fluid, which is then circulated to remove the heat, providing more effective cooling (in comparison to conventional air-based cooling methods). In some cases, however, the immersion cooling fluid may become contaminated by various substances, which can compromise the thermal conductivity of the fluid and cause corrosion, electrical failure, thermal breakdown, etc. Some immersion cooling tanks (also referred to as immersion tanks) may also be subject to unsafe operating conditions (e.g., high temperatures, low fluid levels), which can potentially lead to equipment overheating, corrosion, or complete system failure due to thermal breakdown.

In accordance with aspects of the present disclosure, an immersion cooling system may include an immersion cooling tank equipped with one or more sensors, and an intelligent controller that is configured to monitor operating conditions (such as the temperature, pressure, or opacity) of the immersion cooling tank. The sensors may include at least one temperature sensor, pressure sensor, opacity sensor, and/or fluid level sensor disposed within the immersion cooling tank. The controller may include a control board with one or more processors and memory storing instructions that are executed by the processors to use the various sensors to monitor the immersion cooling tank's environment and perform remedial actions (e.g., shutting off power to the electronic devices immersed in the tank) if unsafe operating conditions (e.g., high temperature and/or pressure, contamination of the cooling fluid, low fluid level, etc.) are detected. In some implementations, the controller is configured to or otherwise capable of communicating with the electronic devices in the tank via a wireless communication protocol like Bluetooth or Wi-Fi.

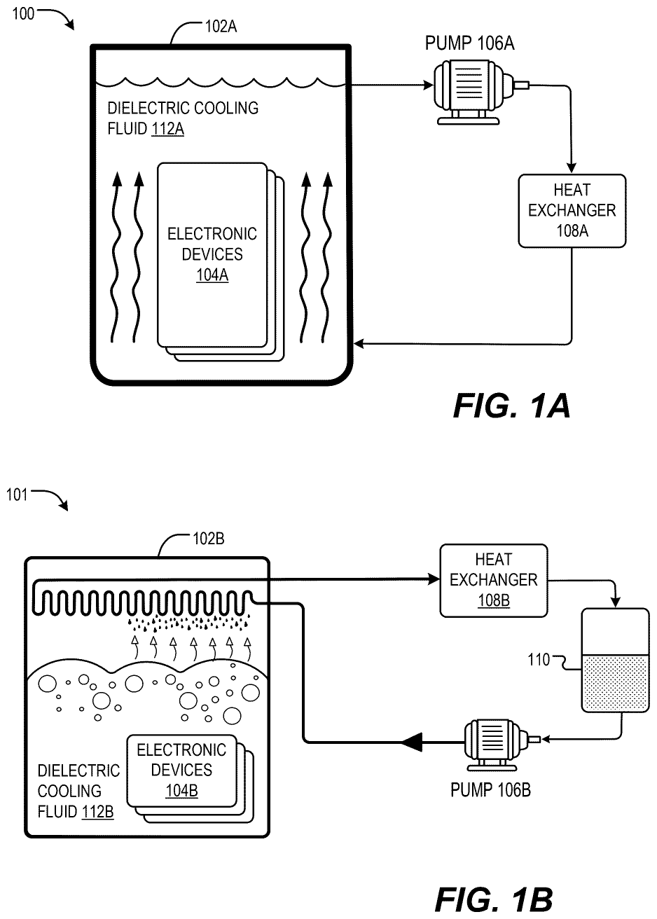

FIG. 1A is a schematic diagram of an example single-phase immersion cooling system 100, according to some implementations. The single-phase immersion cooling system 100 includes a container or tank 102A that holds a volume of dielectric cooling fluid 112A. Electronic devices 104A (e.g., servers, processors, IC chips performing hash computations, or other heat-generating components) are fully immersed in the dielectric cooling fluid 112A. In some implementations, the dielectric cooling fluid 112A is an electrically non-conductive liquid, ensuring safe operation of the electronic devices 104A while maintaining thermal conductivity to absorb the heat produced by the electronic devices 104A during operation.

A pump 106A is configured to circulate the dielectric cooling fluid 112A throughout the tank 102A, ensuring a consistent flow of the dielectric cooling fluid around the electronic devices 104A. Circulating the dielectric cooling fluid 112A through the tank 102A facilitates absorption and distribution of heat away from the heat-generating electronic devices 104A. The dielectric cooling fluid 112A remains in a liquid state (single-phase) during the entire cooling process, avoiding any phase change to gas or vapor.

The single-phase immersion cooling system 100 is further equipped with a heat exchanger 108A that is thermally connected to the circuit of the dielectric cooling fluid 112A. The heat exchanger 108A is responsible for transferring heat absorbed by the dielectric cooling fluid 112A from the electronic devices 104A to an external cooling medium, such as air or water. As the pump 106A drives the dielectric cooling fluid 112A through the heat exchanger 108A, heat is dissipated from the dielectric cooling fluid 112A to the external cooling medium, which cools the dielectric cooling fluid 112A before it is recirculated back to the tank.

During operation, the electronic devices 104A generate heat, which is transferred directly to the surrounding dielectric cooling fluid 112A. The dielectric cooling fluid 112A has a high thermal conductivity, allowing the cooling fluid 112A to efficiently absorb heat and prevent the electronic devices 104A from overheating. The pump 106A circulates the cooling fluid 112A such that hotter fluid 112A is continuously replaced with colder fluid 112A.

As the cooling fluid 112A is circulated, it passes through the heat exchanger 108A, where excess heat is transferred from the cooling fluid 112A to the external cooling medium. The cooled fluid 112A then flows back into the tank 102A to continue the cooling cycle. This process maintains a stable operating temperature for the electronic devices 104A.

FIG. 1B is a schematic diagram of an example dual-phase immersion cooling system 101, according to some implementations. The dual-phase immersion cooling system 101 includes a tank 102B, which holds a volume of dielectric cooling fluid 112A. Electronic devices 104B, such as servers, processors, and other heat-generating components, are fully immersed in the dielectric cooling fluid 112A. The dielectric cooling fluid 112A is electrically non-conductive, which ensures safe operation of the electronic devices 104B while allowing effective thermal conductivity for heat absorption.

Unlike the single-phase immersion cooling system 100, the dielectric cooling fluid 112B of the dual-phase immersion cooling system 101 undergoes a phase change from liquid to vapor as it absorbs heat from the electronic devices 104B. This phase change allows the dual-phase immersion cooling system 101 to manage high thermal loads more efficiently, as compared to the single-phase immersion cooling system 101.

The dual-phase immersion cooling system 101 includes a pump 106B that is configured to circulate the dielectric cooling fluid 112B, ensuring even distribution of the fluid and vapor throughout the tank. The dual-phase immersion cooling system 101 also includes a heat exchanger 108B, which is configured to remove heat from the cooling fluid 112B as part of the cooling cycle. Additionally, the dual-phase immersion cooling system 101 includes a condensation unit 110, where vapors are converted back to liquid by means of coils or other cooling mechanisms.

During operation, the electronic devices 104B generate heat, which is absorbed by the surrounding dielectric cooling fluid 112B. As the cooling fluid 112B absorbs heat, the cooling fluid 112B vaporizes, transitioning from a liquid phase to a vapor phase. This vapor rises within the tank 102B and passes through the heat exchanger 108B before reaching the condensation unit 110, where the vapor is converted back to a liquid. The cooled, recondensed dielectric cooling fluid 112B is then returned to the tank 102B via the pump 106B.

The single-phase immersion cooling system 100 and/or the dual-phase immersion cooling system 101 can provide improved thermal management and reduced energy consumption (e.g., by eliminating any need for traditional air-cooling methods), among other benefits. The use of dielectric cooling fluid prevents electrical interference, and the continuous circulation of dielectric cooling fluid helps to ensure a consistent and efficient dissipation of heat.

Immersion cooling systems for high performance computing applications, both single and dual phase, rely on a consistent, clean source of immersion cooling fluid. Over time (or in the case of specific problems in the cooling tank), this immersion fluid may become contaminated by various substances. This contamination may cause issues with the electronics in the cooled electronic devices, which are open to the cooling fluid to maximize the cooling performed by the fluid.

During operation, immersion tanks may also experience unsafe operating conditions, such as high temperature and/or pressure, fluid contamination, low fluid level, etc. If not remediated, these unsafe operating conditions can cause damage to the electronic devices, the cooling fluid, and/or the tank itself. For example, high temperatures can lead to permanent deformation of circuit boards, fluid contamination can lead to short circuits and other electical malfunctions, and high pressures can damage housings, seals, and other mechanical aspects of the immersion tank.

In accordance with aspects of the present disclosure, the single-phase immersion cooling system 100 and/or the dual-phase immersion cooling system 101 may be equipped with one or more sensors and a controller that are configured to monitor operating conditions (such as the temperature, pressure, or opacity) of the overall system. If unsafe operating conditions are detected, the controller may be configured to take remedial actions, such as powering down electronic devices or transmitting an alert to a system operator.

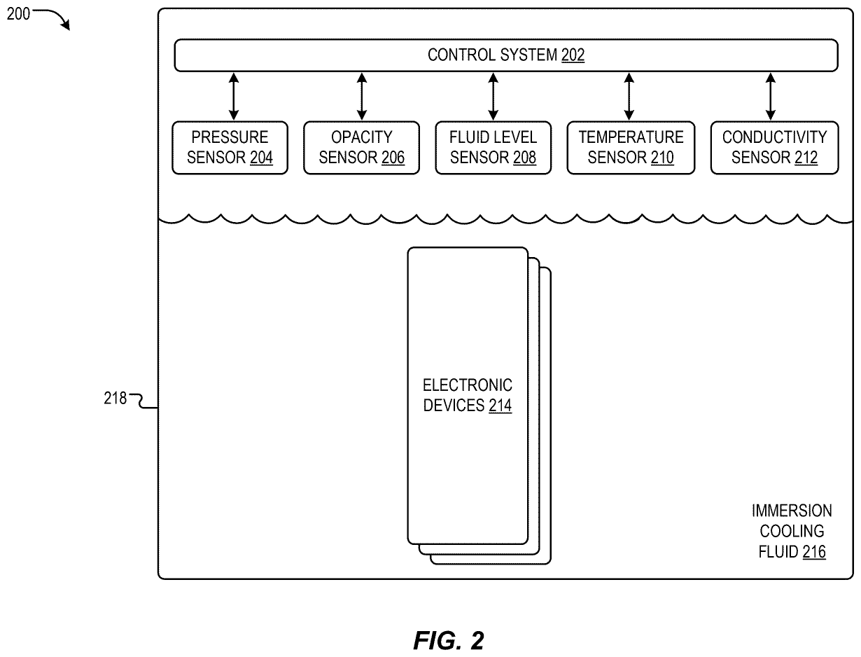

FIG. 2 is a schematic diagram of an example intelligent immersion cooling system 200, according to some implementations. The intelligent immersion cooling system 200 may implement one or more aspects of the single-phase immersion cooling system 100 and/or the dual-phase immersion cooling system 101, as shown and described with reference to FIGS. 1A-1B. For example, the immersion cooling system 200 includes a tank 218, which may be similar to tank 102A or tank 102B. The immersion cooling system 200 also includes immersion cooling fluid 216, which may be similar to the dielectric cooling fluid 112A (e.g., a single-phase cooling fluid) or the dielectric cooling fluid 112B (e.g., a two-phase cooling fluid). One or more electronic devices 214 are immersed in the cooling fluid 216.

The intelligent immersion cooling system 200 includes one or more sensors, such as a pressure sensor 204, an opacity sensor 206, a fluid level sensor 208, a temperature sensor 210, and/or a conductivity sensor 212. These sensors may be configured to monitor various operating conditions of the immersion tank 218. Although the sensors are depicted at the top of the immersion tank 218 in FIG. 2, it should be understood that these sensors can be positioned or otherwise mounted at various locations within (or proximate to) the immersion tank 218. For example, one or more of the sensors may be submerged in the cooling fluid 216.

The pressure sensor 204 may be configured to monitor the pressure within the immersion tank 218 (e.g., to ensure that an operating pressure of the immersion tank 218 does not exceed a threshold pressure), the opacity sensor 206 may be configured to monitor an opacity of the cooling fluid 216 within the immersion tank 218 (e.g., to ensure that contamination levels of the cooling fluid 216 are within an acceptable range), the fluid sensor 208 may be configured to monitor the fluid level of the immersion tank 218 (e.g., to ensure that the amount of cooling fluid 216 in the immersion tank 218 does not drop below a particular threshold), the temperature sensor 210 may be configured to monitor the temperature of the cooling fluid 216 and/or the immersion tank 218 (e.g., to ensure that the temperature of the tank 218 does not exceed a particular threshold), and the conductivity sensor 212 may be configured to monitor the thermal and/or electrical conductivity of the cooling fluid 216 (e.g., to ensure that the cooling fluid 216 does not interfere with the electronic devices 214). The immersion cooling system 200 may also include a meter (such as a capacitance meter, a conductivity meter, or a resistivity meter) that is configured to measure the capacitance and/or resistance of the cooling fluid 216 (e.g., to ensure that the cooling fluid 216 does not interfere with electrical functions of the electronic devices 214.

The intelligent immersion cooling system 200 also includes a control system 202 (equivalently referred to herein as a controller). In some implementations, the control system 202 includes one or more processors mounted on a circuit board within (or coupled to) the immersion tank 218. In some implementations, the control system 202 also includes one or more memory devices storing instructions that, when executed, cause the one or more processors of the control system to manage operating conditions of the tank 218 based on measurements performed by the sensors, as described in this disclosure. The control system 202 may include a microcontroller, a central processing unit, or the like.

One or more of the aforementioned sensors may be configured to identify contamination to allow the system operator to perform maintenance on the tank 218 and/or the fluid 216 to prevent problems from the contamination. For example, the opacity sensor 206 (which can be disposed within the tank 218 or on the electronic control system 202 itself) can measure the opacity or clarity of the cooling fluid 216 to detect contamination levels of the cooling fluid 216. A conductivity sensor 212 can also detect changes in the capacitance or resistance of the fluid and/or detect the presence of foreign matter in the immersion cooling fluid 216.

In some implementations, the control system 202 is configured to communicate with the electronic devices 214 in the tank 218 via a network connection, Wi-Fi, Bluetooth, or some other communication channel. This allows the control system 202 to notify the electronic devices 214 of unsafe operating conditions so the electronic devices 214 can shut themselves down before power to the tank 218 is deactivated, reduced, etc.

The control system 202 can provide a user (such as a system operator) with a warning or alert that the cooling fluid 216 has been contaminated. In conventional immersion cooling systems, if the electronic devices 214 are in operation, the system operator may be unaware of contamination levels until the electronic devices 214 (e.g., high-performance computing devices) become inoperable. Alerting the operator when there is contamination in the cooling fluid 216 allows the operator to address the contamination (for example, by filtering or replacing the cooling fluid 216) before it affects the performance of the electronic devices 214.

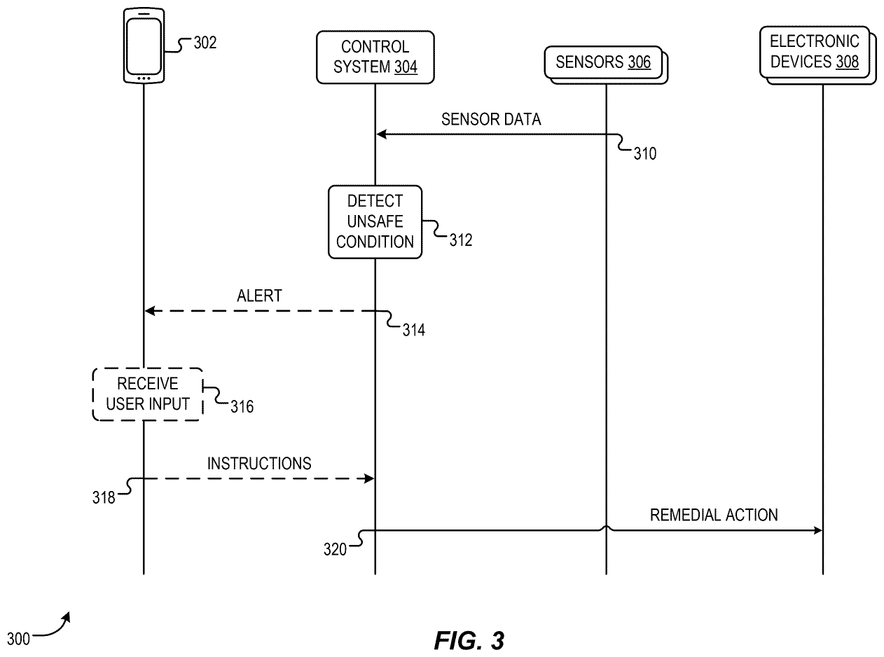

FIG. 3 is an example process flow 300 for managing operating conditions of an intelligent immersion cooling tank, according to some implementations. The example process flow 300 may implement one or more aspects of the preceding figures. For example, the process flow 300 includes a control system 304, which may be an example of aspects of the control system 202 shown and described with reference to FIG. 2. Likewise, the process flow 300 includes electronic devices 308, which may be examples of the electronic devices 214 shown and described with reference to FIG. 2. The process flow 300 also includes a mobile device 302 (such as a smartphone, laptop, or other computing device) and sensors 306 (such as a pressure sensor 204, an opacity sensor 206, a fluid level sensor 208, a temperature sensor 210, and/or a conductivity sensor 212).

At 310, the control system 304 collects measurement data from various sensors 306 positioned within or near an immersion cooling tank (such as the immersion cooling tank 218 shown and described with reference to FIG. 2). For example, the control system 304 may obtain pressure data from a pressure sensor 204, temperature measurements from a temperature sensor 210, conductivity data from a conductivity sensor 212, fluid opacity readings from an opacity sensor 206, fluid level readings from a fluid level sensor 208, etc.

At 312, the control system 304 may detect that at least one operating condition of the immersion tank or the electronic devices 308 is outside of a threshold range defined by an upper threshold (e.g., an upper bound or limit) and a lower threshold (e.g., a lower bound or limit). The operating condition of the immersion tank can include the thermal conductivity of the cooling fluid, e.g., how efficiently the cooling fluid can dissipate heat generated by the electronic devices 308, the electrical conductivity of the cooling fluid (e.g., how well the cooling fluid insulates the electronic devices), the opacity or contamination level of the cooling fluid, the temperature of the immersion tank, the temperature of the cooling fluid, etc. For example, the control system 304 may determine that the thermal conductivity of the cooling fluid is outside of a threshold range (e.g., below a lower threshold) by detecting that the temperature of the immersed electronic devices is above a threshold. Likewise, the control system 304 may determine that a contamination level of the dielectric cooling fluid is unsafe based at least in part on measurements provided by the opacity sensor 206. For example, if the opacity sensor 206 detects that the opacity of the cooling fluid is above a threshold value, the control system 304 may determine that the contamination level of the cooling fluid is outside a threshold range (e.g., above a threshold).

Additionally or alternatively, the control system 304 may detect a leak in the immersion cooling tank based a change in dielectric cooling fluid measured by the fluid level sensor 208. Accordingly, if the fluid level sensor 208 detects that the level of cooling fluid in the immersion tank is below a threshold (e.g., outside a threshold range), the control system 304 may determine that there is a leak in the tank. Additionally, or alternatively, the control system 304 may determine that an operating temperature of the immersion tank is above a threshold temperature (e.g., outside of a safe temperature range) based on measurements provided by the temperature sensor 210. In other examples, the control system 304 may determine that an operating pressure of the immersion tank is above a threshold pressure (e.g., outside of a safe pressure range) based on measurements provided by the pressure sensor 204.

In some implementations, the control system 304 is configured to predict that an operating condition of the electronic devices 308 will depart from the threshold range based on historical measurement data collected by the sensors 306. For example, the control system 304 may access historical temperature data from memory, and may use current temperature readings from the temperature sensor 210 in combination with the historical temperature data to predict that an operating temperature of the immersion tank will exceed a threshold value in a given time period (e.g., in the next 12 hours). Additionally or alternatively, the control system 304 may access historical pressure data from memory, and may use current pressure readings from the pressure sensor 204 in combination with the historical pressure data to predict that an operating pressure of the immersion tank will exceed a threshold value in a given time period. Additionally or alternatively, the control system 304 may access historical opacity data from memory, and may use current opacity readings from the opacity sensor 206 in combination with the historical opacity data to predict that a contamination level of the cooling fluid will exceed a threshold value in a given time period.

At 314, the control system 304 may optionally transmit an alert to the mobile device 302. This alert can serve to notify the system operator of the unsafe operating condition(s) in the immersion cooling tank. At 316, the mobile device 302 may optionally receive a user input in response to displaying the alert from the control system 304. Based on the user input, the mobile device 302 may transmit instructions (such as a command or request) back to the control system 304 at 318. These instructions may cause the control system 304 to perform one or more remedial actions selected by the system operator.

At 320, the control system 304 may perform at least one remedial action in response to determining that at least one property of the dielectric cooling fluid or at least one operating condition of the electronic devices 308 is outside of the threshold range. For example, the control system 304 may transmit a signal that causes one or more of the electronic devices 308 in the immersion tank to shut down or enter a low power state until the at least one property or operating condition is restored to a safe level (e.g., to a value that is within an acceptable range). Additionally, or alternatively, the control system 304 may transmit an indication of the unsafe operating conditions to a fleet management controller that manages computing operations across multiple immersion tanks. In other implementations, performing the remedial action can involve activating a cleaning process to filter or remove contaminants from the dielectric cooling fluid.

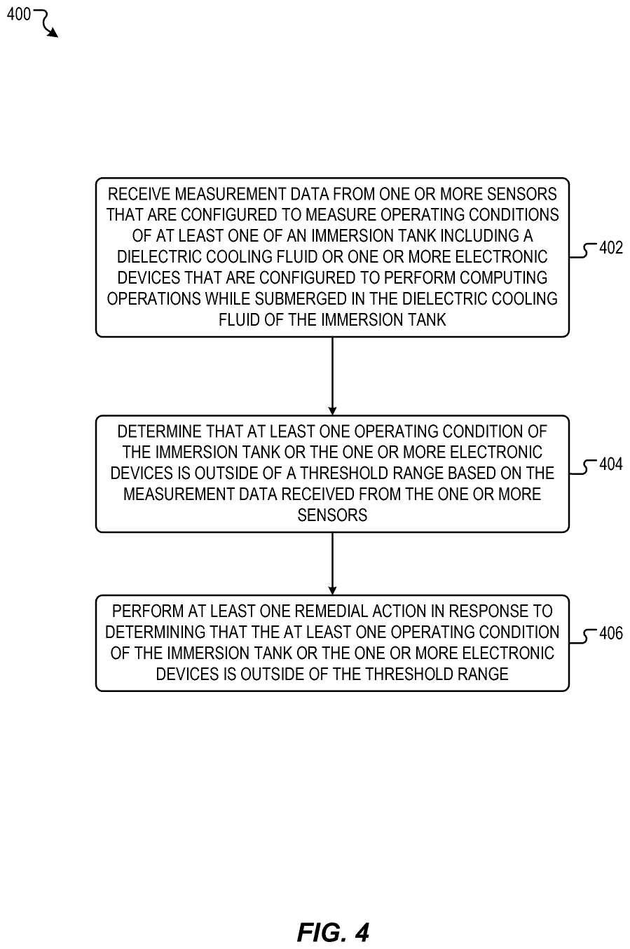

FIG. 4 illustrates a flowchart of an example method 400 for managing operating conditions of an intelligent immersion cooling tank, according to some implementations. For clarity of presentation, the method 400 is generally described in the context of the preceding figures. For example, the method 400 can be performed by the control system 202 of FIG. 202, or any suitable system, environment, software, hardware, or combination thereof. In some implementations, operations of the method 400 can be run in parallel, in combination, in loops, or in any order. The example method 400 can be modified or reconfigured to include additional, fewer, or different steps (not shown in FIG. 4), which can be performed in the order shown or in a different order.

At 402, the method 400 includes receiving measurement data from one or more sensors that are configured to measure operating conditions of at least one of (i) an immersion tank including a dielectric cooling fluid or (ii) one or more electronic devices that are configured to perform computing operations while submerged in the dielectric cooling fluid of the immersion tank.

At 404, the method 400 includes determining that at least one operating condition of the immersion tank or the one or more electronic devices is outside of a threshold range (e.g., a range defined by an upper threshold and a lower threshold) based on the measurement data received from the one or more sensors.

At 406, the method 400 includes performing at least one remedial action in response to determining that the at least one operating condition of the immersion tank or the one or more electronic devices is outside of the threshold range (e.g., below the lower threshold or above the upper threshold).

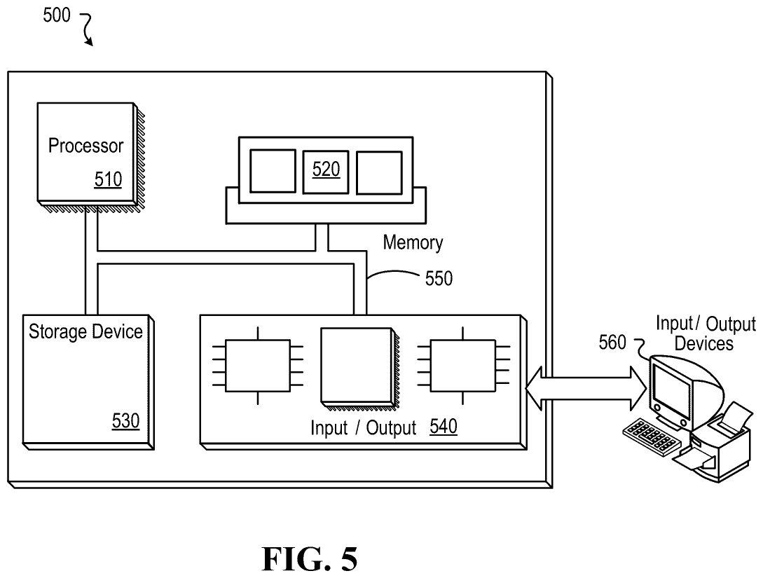

FIG. 5 is a schematic diagram of an example computer system 500. In some implementations, the computer system 500 may include or be a part of one or more of the entities described herein. For example, in some implementations, the computer system 500 is similar to the control system 202 or the control system 304. As depicted in FIG. 5, the computer system 500 includes a processor 510, a memory 520, a storage device 530 and an input/output device 540. Each of these components can be interconnected, for example, by a system bus 550. The processor 510 is capable of processing instructions for execution within the computer system 500. In some implementations, the processor 510 is a single-threaded processor, a multi-threaded processor, or another type of processor. The processor 510 is capable of processing instructions stored in the memory 520 or on the storage device 530. The memory 520 and the storage device 530 can store information within the computer system 500. For example, the memory 520 and/or the storage device 530 can store measurement data from one or more sensors as they are received by the control system, as described in the preceding sections. Additionally or alternatively, the memory 520 and/or the storage device 530 can store historical measurement data. Although the computer system 500 is shown as having one processor 510, one memory 520, and one storage device 530 for illustrative purposes, the computer system 500 can include any number of processors 510, memories 520, and storage devices 530 based on system requirements.

The input/output device 540 provides input/output operations for the computer system 500. In some implementations, the input/output device 540 can include one or more of a network interface device (for example, an Ethernet card), a serial communication device (for example, an RS-232 port), or a wireless interface device (for example, an 802.11 card, a 3G wireless modem, a 4G wireless modem, or a 5G wireless modem), or some combination thereof. In some implementations, the input/output device can include driver devices configured to receive input data and send output data to other input/output devices, for example, a keyboard, printer, and/or display devices 560. In some implementations, mobile computing devices, mobile communication devices, and other devices can also be used.

While the present disclosure describes many examples, these should not be construed as limitations on the scope of an invention that is claimed or of what may be claimed, but rather as descriptions of features specific to particular embodiments. Certain features that are described in the context of separate embodiments can also be implemented in combination in a single embodiment. Conversely, various features that are described in the context of a single embodiment can also be implemented in multiple embodiments separately or in any suitable sub-combination. Although some features may be described as acting in certain combinations and even initially claimed as such, one or more features from a claimed combination in some cases can be excised from the combination, and the claimed combination may be directed to a sub-combination or a variation of a sub-combination. Similarly, while some operations may be depicted in the drawings in a particular order, this should not be understood as requiring that such operations are performed in the particular order shown or in sequential order, or that all illustrated operations be performed, to achieve desirable results.

A number of embodiments have been described. Nevertheless, it is understood that various modifications can be made without departing from the spirit and scope of the present disclosure. Accordingly, other embodiments are within the scope of the following claims.

1. An apparatus comprising:
an immersion tank configured to hold a volume of single-phase dielectric cooling fluid;
one or more electronic devices configured to perform computing operations including hash computations while submerged in the dielectric cooling fluid of the immersion tank;
a plurality of sensors configured to measure respective operating conditions of the immersion tank, wherein the plurality of sensors comprise a fluid level sensor and a temperature sensor, and the respective operating conditions comprise a fluid level and a temperature of the dielectric cooling fluid in the immersion tank; and
a control system comprising one or more processors mounted on a circuit board within the immersion tank at a different location than the one or more electronic devices, the control system configured to:
receive measurement data from the plurality of sensors;
determine that at least one of the fluid level or the temperature of the dielectric cooling fluid is outside of a respective threshold range based at least in part on the measurement data received from the plurality of sensors;
transmitting, to a mobile device associated with a system operator, a notification that the at least one of the fluid level or the temperature of the dielectric cooling fluid is outside of the respective threshold range; and
perform at least one remedial action based on receiving an instruction from the mobile device associated with the system operator, wherein performing the at least one remedial action comprises causing the one or more electronic devices submerged in the dielectric cooling fluid of the immersion tank to enter a low power state.

2. The apparatus of claim 1, wherein causing the one or more electronic devices to enter a low power state comprises transmitting a signal that causes the electronic devices in the immersion tank to shut down or enter a low power state until the respective operating condition of the immersion tank or the one or more electronic devices is restored to the threshold range.

3. (canceled)

4. The apparatus of claim 1, wherein performing the remedial action comprises initiating a cleaning process to filter contaminants from the dielectric cooling fluid based at least in part on determining that a contamination level of the dielectric cooling fluid is above a threshold value.

5. The apparatus of claim 1, wherein the plurality of sensors further comprise a conductivity sensor configured to measure a thermal or electrical conductivity of the dielectric cooling fluid in the immersion tank, and wherein the control system is further configured to:
receive measurement data from the conductivity sensor; and
determine that the thermal or electrical conductivity of the dielectric cooling fluid is outside of the threshold range based at least in part on the measurement data provided by the conductivity sensor.

6. The apparatus of claim 1, wherein the one or more sensors comprise a meter configured to measure a capacitance or resistance of the dielectric cooling fluid in the immersion tank, and
wherein determining that at least one operating condition of the immersion tank or the one or more electronic devices is outside of the threshold range comprises determining that the capacitance or resistance of the dielectric cooling fluid is outside of the threshold range based at least in part on measurements provided by the meter.

7. The apparatus of claim 1, wherein determining that at least one of the fluid level or the temperature of the dielectric cooling fluid is outside of the respective threshold range comprises detecting a leak in the immersion tank based at least in part on a change in the fluid level of the dielectric cooling fluid as measured by the fluid level sensor.

8. The apparatus of claim 1,
wherein determining that at least one of the fluid level or the temperature of the dielectric cooling fluid is outside of the respective threshold range comprises determining that the operating temperature of the dielectric cooling fluid is above a threshold based at least in part on measurements provided by the temperature sensor.

9. The apparatus of claim 1, wherein the one or more sensors comprise a pressure sensor configured to measure an operating pressure of the immersion tank, and
wherein determining that at least one operating condition of the immersion tank or the one or more electronic devices is outside of the threshold range comprises determining that the operating pressure of the immersion tank is above a threshold based at least in part on measurements provided by the pressure sensor.

10. The apparatus of claim 1, wherein the one or more sensors comprise an opacity sensor configured to measure an opacity of the dielectric cooling fluid, and
wherein determining that at least one operating condition of the immersion tank or the one or more electronic devices is outside of the threshold range comprises determining that a contamination level of the dielectric cooling fluid is above a threshold based at least in part on the opacity of the dielectric cooling fluid as measured by the opacity sensor.

11. The apparatus of claim 1, wherein determining that the at least one of the fluid level or the temperature of the dielectric cooling fluid is outside of the respective threshold range comprises:
accessing historical measurement data collected by the plurality of sensors;
analyzing the measurement data received from the plurality of sensors based at least in part on the historical measurement data; and
predicting that an operating condition of the immersion tank or the one or more electronic devices will leave the threshold range based at least in part on the analyzing.

12. The apparatus of claim 1, wherein the control system is configured to communicate with the one or more electronic devices in the immersion tank via a short-range wireless communication protocol.

13. The apparatus of claim 1, wherein the dielectric cooling fluid comprises a single-phase immersion cooling liquid or a two-phase immersion cooling liquid.

14. The apparatus of claim 1, further comprising:
a heat exchanger configured to dissipate heat generated by the one or more electronic devices by means of the dielectric cooling fluid,
wherein performing the remedial action comprises adjusting an operating parameter of the heat exchanger to restore an operating temperature or pressure of the immersion tank to the threshold range.

15. The apparatus of claim 1, further comprising:
a pump system configured to circulate the dielectric cooling fluid through the immersion tank,
wherein performing the remedial action comprises adjusting an operating parameter of the pump system to restore an operating temperature or pressure of the immersion tank to the threshold range.

16-30. (canceled)

31. An apparatus comprising:
an immersion tank configured to hold a volume of dielectric cooling fluid;
one or more electronic devices configured to perform computing operations while submerged in the dielectric cooling fluid of the immersion tank;
one or more sensors configured to measure respective operating conditions of the immersion tank, wherein the one or more sensors comprise a temperature sensor and the respective operating conditions comprise a temperature of the dielectric cooling fluid in the immersion tank; and
a control system comprising one or more processors configured to:
receive measurement data from the one or more sensors;
determine that at least one operating condition of the respective operating conditions is outside of a threshold range based at least in part on the measurement data received from the one or more sensors; and
perform at least one remedial action in response to determining that the at least one operating condition of the immersion tank is outside of the threshold range, wherein performing the at least one remedial action comprises restoring the temperature of the dielectric cooling fluid in the immersion tank to within the threshold range.

32. An apparatus comprising:
an immersion tank configured to hold a volume of dielectric cooling fluid;
one or more electronic devices configured to perform computing operations while submerged in the dielectric cooling fluid of the immersion tank;
one or more sensors configured to measure respective operating conditions of the immersion tank, wherein the one or more sensors comprise an opacity sensor and the respective operating conditions comprise an opacity of the dielectric cooling fluid in the immersion tank; and
a control system comprising one or more processors configured to:
receive measurement data from the one or more sensors;
determine that at least one operating condition of the respective operating conditions is outside of a threshold range based at least in part on the measurement data received from the one or more sensors; and
perform at least one remedial action in response to determining that the at least one operating condition of the immersion tank is outside of the threshold range, wherein performing the at least one remedial action comprises transmitting an alert that the at least one operating condition of the immersion tank is outside of the threshold range.
